(19) United States
(12) Patent Application Publication
(10) Pub. No.: US 2011/0303406 A1
(43) Pub. Date: Dec. 15, 2011

(54) AIR-CONDITIONING SYSTEM AND CONTROL DEVICE THEREOF

(75) Inventors: Jun Takeda, Kawasaki (JP); Nobuyuki Tamura, Kawasaki (JP); Tadashi Katsui, Kawasaki (JP); Masamichi Iwasaki, Kawasaki (JP); Shinji Mizumura, Kawasaki (JP); Hideo Okoshi, Kawasaki (JP)

(73) Assignee: FUJITSU LIMITED, Kawasaki (JP)

(21) Appl. No.: 13/154,838

(22) Filed: Jun. 7, 2011

(30) Foreign Application Priority Data
Jun. 11, 2010 (JP) 2010-134508

(51) Int. Cl. G05D 23/00; H05K 7/20

(52) U.S. Cl. 165/288; 165/104.11

(57) ABSTRACT

A computer room air-conditioning system includes a temperature detection unit which is provided for each of a front and a back of each rack, and measures air temperatures of the front and the back; and a control device for acquiring a measured temperature by each temperature detection unit, and performing control based on the measured temperature. With the configuration, the control device includes a temperature difference calculation unit for calculating a temperature difference between cool air at the front and warm air at the back of each rack based on each measured and acquired temperature; and a heating element cooling control unit for controlling by adjustment an amount of flow of cool air from the underfloor space to the computer room based on the calculated temperature difference.

### CROSS-REFERENCE TO RELATED APPLICATION

This application is based upon and claims the benefit of priority of the prior Japanese Patent Application No. 2010-134508, filed on Jun. 11, 2011, the entire contents of which are incorporated herein by reference.

### FIELD

Some embodiments disclosed here relate to a computer room air-conditioning system.

### BACKGROUND

Well known as a typical example of a computer room air-conditioning system is a system of supplying cool air from an air-conditioning device provided outside a computer room through double flooring and collecting warm air in the room by the air-conditioning device through an attic.

As conventional technology relating to the above-mentioned computer room air-conditioning system, for example, Japanese Laid-open Patent Publication No. 2001-60785 (hereinafter referred to as Patent Document 1) is well known.

In the invention of Patent Document 1, cool air is supplied from under the double flooring to an interior passage of the room, and the problem of overcooling and insufficient cooling of an equipment storage rack caused by a different heating element for each rack in the equipment storage rack in the air-conditioning system for managing the air-conditioning process in the entire room can be solved by controlling the air volume adjusting valve on the double flooring based on four or more air volume detection sensors provided under the double flooring.

### SUMMARY

According to an aspect of the embodiment, a computer room air-conditioning system which is provided with a plurality of racks each storing a heating element, wherein cool air transmitted from an air balancer to a double flooring underfloor space flows into the computer room, the flown-in cool airflows into each rack from a front of the rack to cool the heating element in the rack, thereby turning the cool air into warm air and ejecting the warm air from a back of the rack, and the ejected warm air is collected by the air balancer, cooled by the air balancer, turned into the cool air, and transmitted to the underfloor space, includes: a temperature detection unit provided for each of the front and the back of each rack, and measuring air temperatures of the front and the back; and a control device acquiring a measured temperature by each temperature detection unit, and performing control based on the measured temperature, wherein the control device includes: a temperature difference calculation unit calculating a temperature difference between cool air at the front and warm air at the back of each rack based on each measured and acquired temperature; and a heating element cooling control unit controlling by adjustment an amount of flow of cool air from the underfloor space to the computer room based on the calculated temperature difference.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a configuration of the computer room air-conditioning system according to an embodiment of the present invention;

FIG. 2 is a block diagram of the function of the controller; and

FIG. 3 is a flowchart of the cool air flow amount controlling process by the controller.

### DESCRIPTION OF EMBODIMENTS

Some embodiments are described below with reference to the attached drawings.

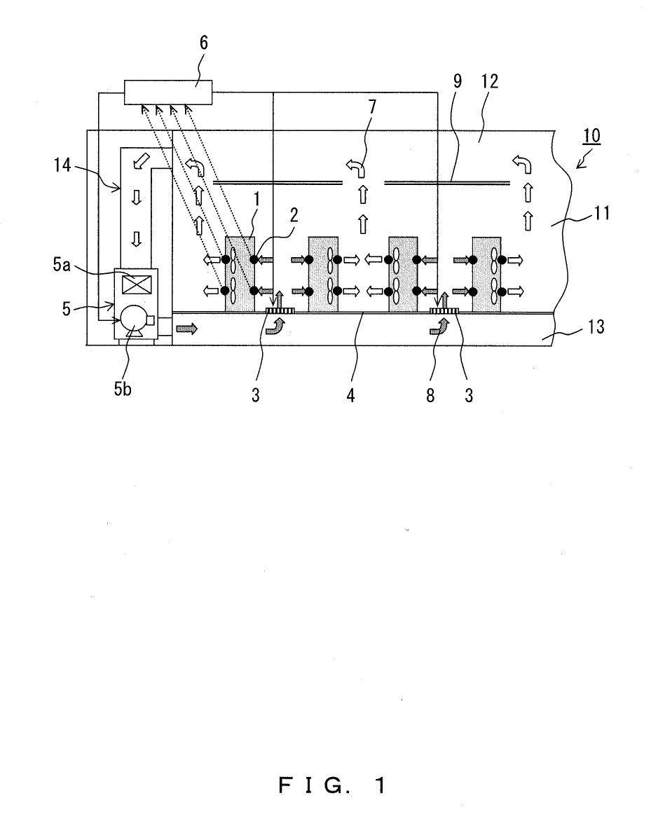

FIG. 1 is a configuration of the computer room air-conditioning system according to an embodiment.

Relating to the computer room air-conditioning system illustrated in FIG. 1, the portions similar to the existing configurations are described first below.

First, a room space 10 encompassed by walls etc. is sectioned into a computer room 11, an attic 12, and an underfloor space 13. The computer room 11 is provided with a plurality of equipment storage racks 1 on a double flooring surface 4. In FIG. 1, four equipment storage racks 1 are illustrated. However, it may also be considered that there are four columns of racks which are formed by an arrangement of plural equipment storage racks 1, and the end equipment storage rack 1 of each column is illustrated. The space below the double flooring surface 4 is the underfloor space 13.

There is, for example, a machine chamber adjacent to the room space 10 outside the room space 10, and a duct 14, an air balancer 5, etc. are provided in the machine chamber. The air balancer 5 collects warm air from the room space 10 through the duct 14, cools the warm air into cool air, and transmits the cool air to the underfloor space 13, thereby supplying the cool air to the room space 10.

The cool air transmitted by the air balancer 5 to the underfloor space 13 flows into the computer room 11 through a cool air supply hole provided in each point (for example, the space between the rack columns such as an interior passage etc.) of the double flooring surface 4. However, in the present example, an air volume adjusting mechanism 3 capable of varying the floor opening rate of the double flooring surface 4 is provided at the point of each cool air supply hole. The air volume adjusting mechanism 3 can adjust the volume of air (amount of flow of cool air) which flows into the computer room 11 from the underfloor space 13 for each cool air supply hole.

Increasing and decreasing the amount of flow of cool air from the underfloor space 13 to the computer room 11 refer to the increase and decrease of the amount of supply of cool air to each heating element in each rack 1.

The air volume adjusting mechanism 3 is an existing configuration disclosed by, for example, Reference Document 1 (Japanese Laid-open Patent Publication No. 2009-180425) and Reference Document 2 (Japanese Laid-open Patent Publication No. 2003-166729), and is therefore not specifically described in detail here.

The cool air which has flown into the computer room 11 as described above flows into each equipment storage rack 1 from the front thereof. Each equipment storage rack 1 includes various information equipment/electronic equipment such as a server device, a communication device, etc. (they are hereinafter referred to generally as a “computer”). The computer such as the server device etc. functions as a heating element during operation. The cool air which has flown into the equipment storage rack 1 is warmed into warm air by cooling the heating element, and ejected from the back of the equipment storage rack 1. Although an intake and exhaust fan is provided in each equipment storage rack 1, it is not specifically explained here.

At a space between the equipment storage rack 1 (between the rack columns), the air volume adjusting mechanism 3 is provided to reserve a space (cool air space) for supply of cool air from the underfloor space 13 and a space (warm air space) for ejection of warm air from the equipment storage rack 1. The side facing the cool air space on the equipment storage rack 1 is called the front, and the side facing the warm air space is called the back.

Since warm air rises, the warm air ejected from the back of the equipment storage rack 1 to the warm air space rises as illustrated in FIG. 1, enters the attic 12 above the ceiling surface 9, and flows into the duct 14. The air balancer 5 cools the warm air collected through the duct 14 into cool air, and transmits the cool air to the underfloor space 13 as described above.

Although not specifically described here because it is an existing item, the air balancer 5 has a evaporator (cooling coil) 5a, a air handling unit 5b, etc. as roughly illustrated in FIG. 1. Although not illustrated in FIG. 1, but as it is well known, a configuration of supplying a coolant etc. to the cooling coil 5a is further included. The warm air collected through the duct 14 becomes cool air by being cooled by the cooling coil 5a, and the cool air is flown into the underfloor space 13 by the air handling unit 5b.

Based on the existing configuration as explained above, the present method further includes the following new configuration.

First, as described above, there is the air volume adjusting mechanism 3 capable of varying the floor opening rate of the double flooring surface 4. That is, there is the air volume adjusting mechanism 3 provided for adjusting the volume of cool air (amount of flow of cool air) to be flown from the underfloor space 13 into the computer room 11. The volume of cool air (amount of flow of cool air) to be flown from the underfloor space 13 into the computer room 11 depends on the floor opening rate of the air volume adjusting mechanism 3 and the amount of handled air of the air handling unit 5b. That is, for example, when the floor opening rate is fixed, the amount of flow of cool air increases if the amount of handled air of the air handling unit 5b increases, and it decreases if the amount of handled air decreases. Similarly, when the amount of handled air of the air handling unit 5b is fixed, the amount of flow of cool air increases if the floor opening rate is higher, and the amount of flow of cool air decreases if the floor opening rate is lower.

Furthermore, a temperature sensor 2 is provided on the front and the back of the rack for each air volume adjusting mechanism 3. That is, each rack 1 provide the temperature sensor 2 for measuring the temperature of the cool air which flows from the front into the rack and the temperature sensor 2 for measuring the temperature of the warm air which is ejected from the back of the rack. That is, a pair of the temperature sensors 2 for respectively measuring the front temperature and the back temperature of the rack 1 is provided for each rack 1. Furthermore provided is a controller 6 for controlling the floor opening rate in the air volume adjusting mechanism 3 and the amount of handled air (number of revolutions of the fan) of the air handling unit 5b.

The controller 6 and each temperature sensor 2 are connected through a data line not illustrated in FIG. 1, and the controller 6 can collect the measured temperature data from each temperature sensor 2 through the data line. The dotted line arrows from the respective temperature sensors 2 of the rack 1 illustrated on the left of FIG. 1 to the controller 6 refer to the data lines. These dotted line arrows are not illustrated for other racks 1, but as described above, they have respective data lines.

In addition, the pair of front and back temperature sensors 2 for each rack 1 is not limited to one pair for each rack 1, but a plurality of pairs can be provided for each rack 1. In the example illustrated in FIG. 1, the pair of temperature sensors 2 is provided for each of the upper and the lower columns in each rack 1. That is, two pairs of sensors are provided for each rack 1.

The controller 6 and each air volume adjusting mechanism 3, and the controller 6 and the air handling unit 5b are connected through the control line illustrated by the solid line arrows illustrated in FIG. 1, and the controller 6 controls by adjustment the floor opening rate in the air volume adjusting mechanism 3 and the amount of handled air (number of revolutions of the fan) of the air handling unit 5b through the control lines.

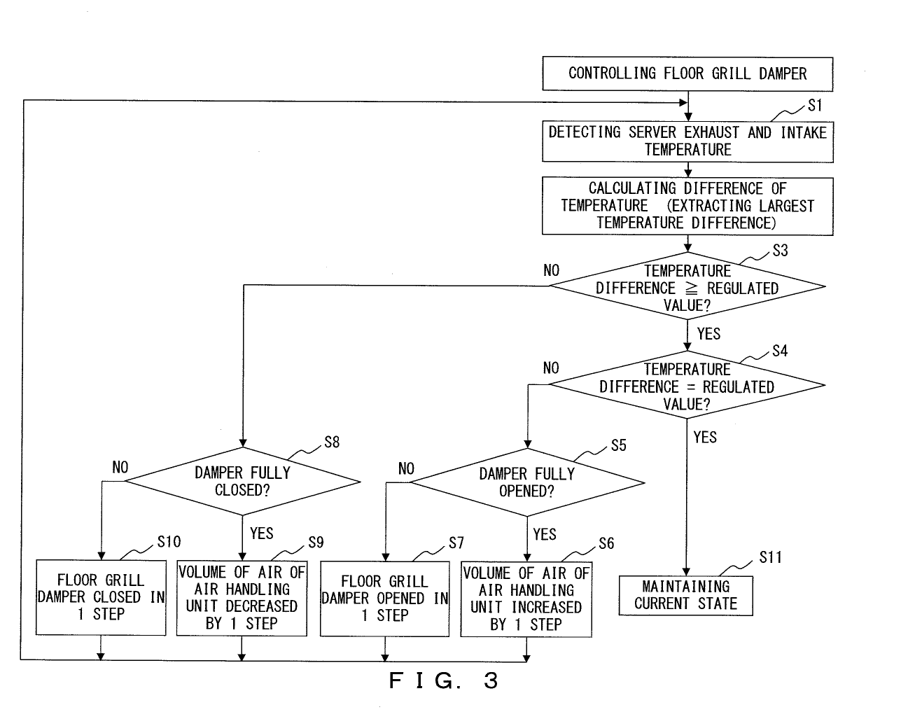

The controller 6 inputs each temperature measured by each temperature sensor 2, performs the process illustrated in FIG. 3 and described later based on the measured temperature, and controls the amount of handled air of the air handling unit 5b and the opening rate of the air volume adjusting mechanism 3, thereby appropriately adjusting the volume of cool air (amount of flow of cool air) which flows into the computer room 11 from each point of the computer room 11. An appropriately adjusted amount of flow of cool air can be obtained depending on the heating condition of a heating element by performing control based on the “temperature difference” especially described later.

Thus, the event in which an abnormal condition (fault etc.) occurs at least due to insufficient cooling can be prevented.

The heating element in the computer room air-conditioning system is basically a computer such as a server device etc. as described above, and the heating value can increase by, for example, temporarily increasing a process load. In the present method, a change of the above-mentioned heating value appears as a change of the “temperature difference”. Therefore, the insufficient cooling of the heating element can be suppressed by increasing the amount of flow of cool air by, for example, the process illustrated in FIG. 3.

On the other hand, since only an entry temperature is checked in the conventional technology, the change of a heating value is not known, and thereby it becomes possible that the heating element is insufficiently cooled. Alternatively, to avoid the insufficient cooling even in the above-mentioned condition, the set temperature of cool air and the set value of volume of air may be the values depending on the conditions for large heating values. In this case, overcooling normally occurs, which is not a problem from the viewpoint of no abnormal conditions (fault etc.) in the heating element such as a server device etc. However, since overcooling occurs almost constantly, power consumption increases, thereby causing a problem from the viewpoint of energy saving.

In this respect, according to the present method, although the power consumption may increase during the increase of the temporary heating value as described in the example above, the power consumption can be low in the period in which the heating value is relatively low, hereby resulting in the power consumption depending on the practical heating condition of a heating element, suppressing wasteful increase of power consumption, and obtaining a preferable energy saving effect as compared with the conventional technology.

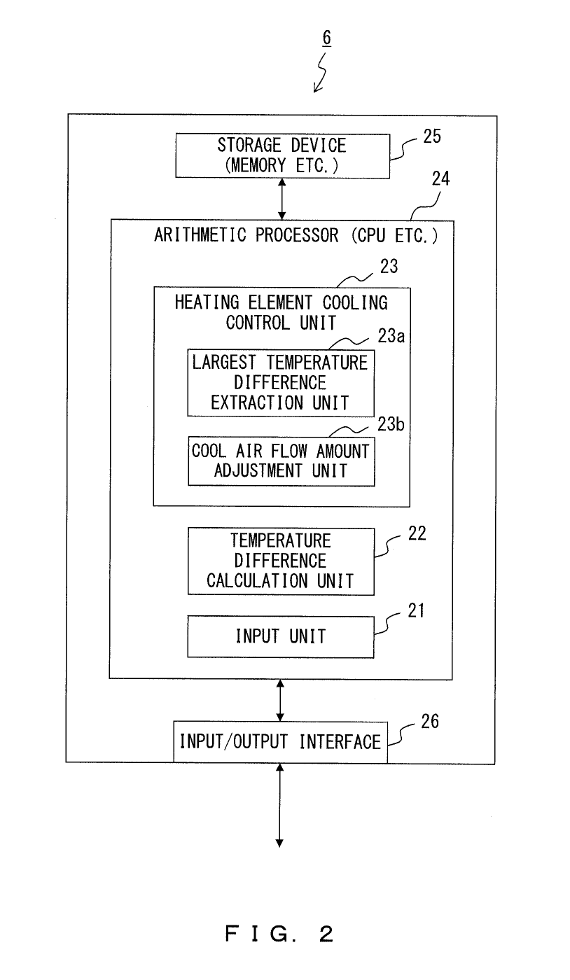

Although not specifically illustrated in FIG. 1, the controller 6 has an input/output interface, etc. for inputting data and outputting a control signal which is connected to an arithmetic processor such as a CPU, an MPU, etc., a storage device such as memory etc., each of the temperature sensors 2, the air handling unit 5b, the air volume adjusting mechanism 3, etc. The storage device stores a predetermined application program, and the CPU etc. reads and executes the program, thereby realizing the function of each function unit illustrated in FIG. 2 and a process illustrated in FIG. 3 as described later.

FIG. 2 is a block diagram of the function of the controller 6.

In FIG. 2, the controller 6 includes an input unit 21, a temperature difference calculation unit 22, a heating element cooling control unit 23, etc. The heating element cooling control unit 23 includes a largest temperature difference extraction unit 23a, a cool air flow amount adjustment unit 23b, etc. The controller 6 includes an above-mentioned arithmetic processor (CPU etc.) 24, a storage device (memory etc.) 25, an input/output interface 26. The input/output interface 26 is connected to a signal line which is connected to each of the temperature sensors 2, the air handling unit 5b, the air volume adjusting mechanism 3, etc. The storage device (memory etc.) 25 stores various types of information, the predetermined application program, etc.

By the arithmetic processor 24 reading and executing the application program stored in advance in the storage device 25, the function of the process performed by each function unit such as the input unit 21, the temperature difference calculation unit 22, the heating element cooling control unit 23 (the largest temperature difference extraction unit 23a, the cool air flow amount adjustment unit 23b), etc. is realized.

The input unit 21 is a function unit for inputting and acquiring data from an external unit through the input/output interface 26, and especially inputs and acquires each measured temperature by each temperature sensor 2 (thus, the input unit 21 may be called a measured temperature acquisition unit 21).

The temperature difference calculation unit 22 calculates the temperature difference between the cool air at the front and the warm air at the back of the rack 1 for each rack 1 based on each measured temperature acquired by the input unit 21.

The heating element cooling control unit 23 controls by adjustment the amount of flow of cool air from the underfloor space 13 to the computer room 11 based on the temperature difference for each rack calculated by the temperature difference calculation unit 22.

As described above, the heating element cooling control unit 23 is configured by, for example, the largest temperature difference extraction unit 23a, the cool air flow amount adjustment unit 23b, etc. and realizes the control by adjustment of the amount of flow of cool air by these units.

That is, the largest temperature difference extraction unit 23a first compares the temperature differences for each rack 1 calculated by the temperature difference calculation unit 22, and extracts the largest temperature difference.

The cool air flow amount adjustment unit 23b compares the largest temperature difference extracted by the largest temperature difference extraction unit 23a with a preset (stored in the storage device 25) and predetermined regulated value, and when the largest temperature difference is larger than the regulated value, it controls the increase of the amount of flow of cool air from the underfloor space 13 to the computer room 11. On the other hand, when the largest temperature difference is smaller than the regulated value, it controls the decrease of the amount of flow of cool air from the underfloor space 13 to the computer room 11.

The cool air flow amount adjustment unit 23b controls by increasing or decreasing the amount of handled cool air of (the air handling unit 5b of) the air balancer 5, or controls by increasing or decreasing the opening rate of the air volume adjusting mechanism 3, thereby increasing or decreasing the amount of flow of cool air from the underfloor space 13 to the computer room 11. The controlling operations can be realized by transmitting a control signal to the air handling unit 5b and the air volume adjusting mechanism 3 through the input/output interface 26.

FIG. 3 is a flowchart of the cool air flow amount controlling process by the controller 6.

For example, the controller 6 periodically (every 5 seconds, every 10 seconds, etc.) performs the process in FIG. 3. First, a measured temperature is collected from each temperature sensor 2 (step S1). That is, relating to all equipment storage racks 1, the front air temperature (cool air temperature) and the back air temperature (warm air temperature) are collected. It also refers to collecting the intake temperatures and the exhaust temperatures of the racks.

Then, the temperature difference is calculated for each equipment storage rack 1 (step S2). The temperature difference is calculated by “back air temperature—front air temperature”. That is, the temperature difference between the temperature of the cool air flowing into the rack and the temperature of the warm air ejected from the rack is obtained for each rack 1. It can be referred also to obtaining a temperature difference between the intake temperature and the exhaust temperature of a rack. When there are plural pairs of temperature sensors 2 for each rack, the temperature difference calculated for each rack 1 may also refer to the temperature difference for each pair and may also refer to an average value of the temperature differences of plural pairs.

When the temperature differences are obtained for all racks as described above, the amount of flow of cool air into the computer room 11 is controlled by adjustment based on the temperature differences. The adjustment of the amount of flow of cool air is realized by, for example, controlling the amount of handled air by the air handling unit 5b and the opening rate of the air volume adjusting mechanism 3.

There may be various processes of controlling the amount of flow of cool air into the computer room 11 based on the calculated temperature difference. However, since the current heating condition of the heating element is reflected by the “temperature difference”, an appropriate adjustment of the amount of flow of cool air can be performed depending on the heating condition of the heating element.

For example, the processes (steps S3 through S11) in and after step S3 may be performed on each “temperature difference” calculated for each rack in step S2. However, in the present example, the processes in and after step S3 are performed using the “largest temperature difference” as described below. It is an example of a insignificant control being performed such that the process for the possibility of NO in step S3 for a rack 1 and NO in step S4 for other racks 1 by different heating condition of a heating element for each rack 1, thereby causing a step up (step S6) by the air handling unit by volume of air of 1 immediately after a step down (step S9) by air handling unit by volume of air of 1, thereby performing insignificant control.

Therefore, in this process example above but limited to this process example above, using the “largest temperature difference”, at least an insufficiently cooled heating element can be prevented without the above-mentioned insignificant control and can prevent the heating element from being insufficiently cooled.

In the process example, first in step S2, when the “temperature difference” is calculated for each rack as described above, the temperature differences are compared with each other to extract the largest temperature difference (step S2). Using the extracted value (largest temperature difference), the determining processes in steps S3 and S4 are performed.

That is, in steps S3 and S4, it is determined which is true, “largest temperature difference>regulated value”, “largest temperature difference=regulated value”, or “largest temperature difference<regulated value”.

First in step S3, it is determined whether or not “largest temperature difference regulated value” is true. If not, that is, if “largest temperature difference<regulated value” (NO in step S3), control is passed to step S8. For the regulated value, any value can be determined and set preliminarily.

If “largest temperature difference<regulated value” (NO in step S3), it is regarded as overcooling, and control is performed to reduce the volume of cool air (amount of flow of cool air) which flows into the computer room 11. The adjustment by the air volume adjusting mechanism 3 is prioritized. That is, it is determined whether or not the damper is fully opened for the air volume adjusting mechanism 3 (step S8). If the damper is not fully opened (NO in step S8), control is performed to close the damper for 1 step (step S10). On the other hand, when the damper is fully closed (YES in step S8), the amount of handled air of the air handling unit 5b is reduced by the amount for 1 step (reduce the number of rotations of the fan) (step S9).

The amount for 1 step refers to a predetermined amount. By repeatedly performing the process in FIG. 3, for example, if the determination in step S8 is repeatedly YES, then the amount of handled air (number of rotation of the fan etc.) is gradually decreased by reducing the amount of handled air step by step.

The damper (floor grill damper) refers to a practical example of the air volume adjusting mechanism 3. For example, it is a damper etc. for adjustment of the volume of air used for a duct etc., and there is a commercial product of a damper. The damper varies the floor opening rate, the “fully closed damper” referring to the opening rate is a predetermined lowest value but the “fully closed damper” does not refer to completely closing (opening rate=0). Therefore, if the amount of handled air of the air handling unit 5b is reduced in the “fully closed damper” state, the volume of cool air (amount of flow of cool air) which flows into the computer room 11 decreases.

In addition, as described in FIG. 1, if there are a plurality of dampers (air volume adjusting mechanisms 3) to be controlled so that they can be closed for one step in step S10, all dampers may be controlled, or only the damper closest to the rack indicating the “largest temperature difference” may be controlled.

The controller 6 includes the information registered in advance which indicates each of the signal line connected to the controller 6 corresponds to which temperature sensor 2 in each rack 1, which temperature sensors 2 make a pair, and which is the closest damper (air volume adjusting mechanism 3) to each rack 1.

In addition, if the determination in step S3 is YES, the determination (largest temperature difference=regulated value?) is performed in step S4, then it is determined which is the current state, “largest temperature difference>regulated value” or “largest temperature difference=regulated value”. If it is determined “largest temperature difference=regulated value” (YES in step S4), then it is regarded that the current state is appropriate cooling of a heating element in each rack (it is regarded that at least there is no insufficiently cooled heating element), and the current state is maintained without performing any process (step S11).

On the other hand, when the “largest temperature difference>regulated value” (NO in step S4), it is regarded as insufficient cooling, and the control to increase the amount of cool air (amount of flow of cool air) which flows into the computer room 11 is performed. In this case, the adjustment by the air volume adjusting mechanism 3 is prioritized. That is, it is determined for the air volume adjusting mechanism 3 as to whether or not the damper is fully opened (step S5). If the damper is not fully opened (NO in step S5), control is performed to open the damper for one step (step S7). On the other hand, if the damper is fully opened (YES in step S5), control is performed to increase the amount of handled air of the air handling unit 5b by the amount for one step (the number of revolutions of the fan is increased etc.) (step S6).

By increasing or decreasing the amount of flow of cool air from the underfloor space 13 to the computer room 11 as described above, the amount of cool air which flows into each rack 1 may be increased or decreased, and the amount of cool air to be supplied to the heating element accommodated in the rack 1 is increased or decreased. Increasing the amount of cool air naturally indicates the enhanced cooling capability for the heating element, and although the heating value of the heating element temporarily increases and insufficient cooling occurs, appropriate cooling can be realized in time by increasing the amount of flow of cool air.

As described above, control is performed in the present method based on the “temperature difference (of the heating element)” not the conventional entry temperature (cool air temperature). The effect of the method is described below.

First, the heating value of the heating element as a server device etc. varies depending on the operation state of the CPU etc. Basically, if the operation rate (power consumption) of the CPU etc. is low, the heating value is also reduced, and the higher the operation rate (power consumption) is, the larger the heating value becomes. However, since there is no definite relationship between the operation rate (power consumption) and the heating value, the heating value cannot be estimated by monitoring the amount of power consumption. On the other hand, in the present method, the “temperature difference” reflects the heating value.

To be extreme, when there is no operation, heat is not generated. Therefore, the temperature difference is nearly “0” in this case, and is expressed by “largest temperature difference<regulated value”. In this case, it is not necessary to cool air, and the amount of flow of cool air is reduced.

On the other hand, if the operation rate of the CPU etc. is high, and the heating value is large, the temperature difference between the front and back of the heating element is large. If the cool air temperature and the amount of flow of cool air are fixed, then the larger the heating value is, the larger the temperature difference becomes. When the temperature difference is too large, the heating element is not sufficiently cooled (insufficient cooling). Then, is the volume of air is increased, the temperature difference becomes smaller, thereby solving the problem of insufficient cooling.

For example, when the temperature difference is measured in advance in the appropriate cooling state in an experiment etc. without insufficient cooling or overcooling, the temperature difference in the appropriate cooling state is set as the “regulated value”, and the determination in step S4 is YES, the appropriate cooling is realized on the heating element. Therefore, controlling the cooling state as described above and maintaining this state realize the appropriate cooling.

However, in the process in FIG. 3 as described above, since the control is performed based on the largest temperature difference, appropriate cooling is performed on the rack (its heating element) indicating the largest temperature difference, and there is a strong possibility that overcooling occurs on other racks (their heating elements). Therefore, the above-mentioned wasteful power consumption occurs. However, if the process is assigned substantially evenly to each server device, there is a small possibility that a large difference in heating value of each server device occurs, and there is the small possibility that considerable waste (power consumption) occurs although the control based on the largest temperature difference is performed. In addition, although the heating value becomes high due to the temporary increase of process load on any server device, and wasteful power consumption occurs by the increase, it is a temporary event, and the energy saving effect is higher as compared with the conventional technology.

As an existing method, there is a method of measuring only the front air temperature (temperature of cool air which flows into rack: entry temperature) of a rack. In this method, for example, a predetermined value which is considered to be appropriate for cooling a heating element is determined and set in advance, and the measured entry temperature is compared with the predetermined value. If the entry temperature is higher than the predetermined value, control is performed to lower the entry temperature. If the entry temperature is lower than the predetermined value, control is performed to rise the entry temperature, thereby performing control to make the entry temperature nearly equal to the predetermined value.

That is, in this existing method, the operation state of the CPU etc. or the current state of the heating element such as a heating value etc. are not considered. Although the entry temperature is maintained at a predetermined value, the insufficient cooling may occur if the heating value is very large. In any case, in the existing method, only the entry temperature is checked, and only the condition of supply of cool air is known. Therefore, it is not known whether or not appropriate cooling is performed on the heating element.

Although the power supply to the CPU may be monitored, the heating value cannot be estimated based on the power supply as described above.

On the other hand, according to the present method, not only the entry temperature but also the exit temperature (air temperature at the back of a rack, temperature of warm air ejected from a rack) is measured to perform control based on the temperature difference. Accordingly, if the heating value increases, the temperature difference also increases.

Therefore, control is performed to increase the volume of air depending on the temperature difference, thereby appropriate cooling can be realized on the heating element without insufficient cooling.

Additionally, in the existing technology, to avoid insufficient cooling, a margin is to be included in a set value (for example, settings are evenly made depending on the largest heating value), which causes a problem from the viewpoint of energy saving. On the other hand, in the predetermined method, appropriate control can be performed depending on the real-time heating condition of a heating element, and an energy-saving effect can be acquired. When overcooling occurs, the amount of handled air of the air balancer (air handling unit 5b) can be decreased, thereby contributing to energy saving.

Thus, according to the present method, the amount of flow of cool air is controlled by adjustment based on the temperature difference between the front and back each equipment storage rack (for example, by controlling the open/close level of the air volume adjusting mechanism which can vary the floor opening rate of the double flooring surface, and the amount of handled air of the air balancer), thereby appropriately cooling the heating element (computer etc.) in the equipment storage rack. Especially, the insufficient cooling can be prevented. A heating element can be appropriately cooled because the temperature difference between the front and back the rack reflects the heating condition of the heating element, and the amount of flow of cool air can be controlled by adjustment depending on the heating condition of the heating element. Furthermore, since it is not necessary to perform overcooling including the margin, an energy-saving effect can also be acquired.

In some of the above-mentioned embodiments, increasing and decreasing the amount of flow of cool air from the underfloor space to the computer room may refer to increasing and decreasing the amount of supply of cool air to each heating condition in each rack. The heating element is, for example, a computer etc. such as a server device etc., and the heating value may be varied depending on the operation state (process load) etc. The temperature difference may reflect the heating value.

Therefore, by controlling by adjustment the amount of flow of cool air based on the temperature difference, the appropriate supply of cool air can be performed depending on the current heating value of the heating element.

According to the computer room air-conditioning system of some of the embodiments above, the control device thereof, the program thereof, etc., the amount of flow of cool air is controlled by adjustment based on the temperature difference between the front and back each equipment storage rack, thereby adjusting the amount of flow of cool air depending on the heating condition of the heating element in the equipment storage rack, and performing appropriate cooling management on the heating element in the equipment storage rack. Furthermore, energy saving can be realized in the interior air-conditioning system.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A computer room air-conditioning system which is provided with a plurality of racks each storing a heating element, wherein cool air transmitted from an air balancer to a double flooring underfloor space flows into the computer room, the flown-in cool air flows into each rack from a front of the rack to cool the heating element in the rack, thereby turning the cool air into warm air and ejecting the warm air from a back of the rack, and the ejected warm air is collected by the air balancer, cooled by the air balancer, turned into the cool air, and transmitted to the underfloor space, comprising:
a temperature detection unit provided for each of the front and the back of each rack, and measuring air temperatures of the front and the back; and
a control device acquiring a measured temperature by each temperature detection unit, and performing control based on the measured temperature, wherein
the control device comprises:
a temperature difference calculation unit calculating a temperature difference between cool air at the front and warm air at the back of each rack based on each measured and acquired temperature; and
a heating element cooling control unit controlling by adjustment an amount of flow of cool air from the underfloor space to the computer room based on the calculated temperature difference.

2. The system according to claim 1, wherein
the heating element cooling control unit comprises:
a largest temperature difference extraction unit comparing temperature differences calculated by the temperature difference calculation unit for each rack, and extracting a largest temperature difference; and
a cool air flow amount adjustment unit comparing the largest temperature difference extracted by the largest temperature difference extraction unit with a predetermined regulated value, increasing the amount of flow of cool air from the underfloor space to the computer room when the largest temperature difference is larger than the regulated value, and decreasing the amount of flow of cool air from the underfloor space to the computer room when the largest temperature difference is smaller than the regulated value.

3. The system according to claim 2, further comprising
an opening rate adjustment unit provided for each opening made in each position of the double flooring, and varying an opening rate of the opening, wherein
the cool air flow amount adjustment unit controls by increasing and decreasing an amount of handled cool air of the air balancer or controls by increasing and decreasing the opening rate of the opening rate adjustment unit, thereby increasing and decreasing the amount of flow of cool air from the underfloor space to the computer room.

4. The system according to any of claim 1, wherein
the heating element is a computer.

5. A control device in a computer room air-conditioning system which is provided with a plurality of racks each storing a heating element, wherein cool air transmitted from an air balancer to a double flooring underfloor space flows into the computer room, the flown-in cool air flows into each rack from a front of the rack to cool the heating element in the rack, thereby turning the cool air into warm air and ejecting the warm air from a back of the rack, and the ejected warm air is collected by the air balancer, cooled by the air balancer, turned into the cool air, and transmitted to the underfloor space, comprising:
a measured temperature acquisition unit acquiring each measured temperature from each temperature detection unit provided for each of the front and the back of each rack, and measuring air temperatures of the front and the back;
a temperature difference calculation unit calculating a temperature difference between the front and the back of each rack based on each measured temperature acquired by the measured temperature acquisition unit; and
a heating element cooling control unit controlling by adjustment an amount of flow of cool air from the underfloor space to the computer room based on the calculated temperature difference.

6. A non-transitory storage medium storing a program to cause a control device in a computer room air-conditioning system which is provided with a plurality of racks each storing a heating element, wherein cool air transmitted from an air balancer to a double flooring underfloor space flows into the computer room, the flown-in cool air flows into each rack from a front of the rack to cool the heating element in the rack, thereby turning the cool air into warm air and ejecting the warm air from a back of the rack, and the ejected warm air is collected by the air balancer, cooled by the air balancer, turned into the cool air, and transmitted to the underfloor space, to perform the process comprising:
acquiring each measured temperature from each temperature detection unit provided for each of the front and the back of each rack, and measuring air temperatures of the front and the back;
calculating a temperature difference between the front and the back of each rack based on each measured and acquired temperature; and
controlling by adjustment an amount of flow of cool air from the underfloor space to the computer room based on the calculated temperature difference.
